(19) United States
(12) Patent Application Publication
(10) Pub. No.: US 2023/0356354 A1
(43) Pub. Date: Nov. 9, 2023

(54) COMPLIANT INNER RING FOR A CHEMICAL MECHANICAL POLISHING SYSTEM

(71) Applicant: Applied Materials, Inc., Santa Clara, CA (US)

(72) Inventors: Jeonghoon Oh, Saratoga, CA (US); Andrew Nagengast, Sunnyvale, CA (US); Steven M. Zuniga, Soquel, CA (US); Eric L. Lau, Santa Clara, CA (US); Hari Prasath Rajendran, Coimbatore (IN); Satish Radhakrishnan, San Jose, CA (US); Kuen-Hsiang Chen, Sunnyvale, CA (US); Ekaterina A. Mikhaylichenko, San Jose, CA (US)

(73) Assignee: Applied Materials, Inc., Santa Clara, CA (US)

(21) Appl. No.: 17/735,655

(22) Filed: May 3, 2022

(51) Int. Cl. B24B 37/32; B24B 37/04

(52) U.S. Cl. CPC B24B 37/32; B24B 37/042

(57) ABSTRACT

Exemplary carrier heads for a chemical mechanical polishing apparatus may include a carrier body. The carrier heads may include a substrate mounting surface coupled with the carrier body. The carrier heads may include an inner ring that is sized and shaped to circumferentially surround a peripheral edge of a substrate positioned against the substrate mounting surface. The inner ring may be characterized by a first end having a first surface that faces the carrier body and a second end having a second surface opposite the first surface. The second end of the inner ring may be radially displaceable. The carrier heads may include an outer ring having an inner surface that is disposed against an outer surface of the inner ring.

### TECHNICAL FIELD

The present technology relates to semiconductor systems, processes, and equipment. More specifically, the present technology relates to polishing film deposited on a substrate.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications, e.g., planarization of a dielectric layer for photolithography, an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. Abrasive polishing slurry is typically supplied to the surface of the polishing pad.

One problem in CMP is uniformly polishing the entire surface of the substrate. Oftentimes, due to the design of CMP systems the regions of the polishing pad proximate the peripheral edges, and in particular proximate the leading and/or trailing edge, of the substrate may be subject to higher or lower polishing rates. For example, as the substrate and polishing pad are moved relative to one another, a trailing edge of the substrate may contact an inner retaining ring, which may generate a side load on the substrate. The side load may be concentrated at the contact point of the trailing edge, which may generate higher polishing rates at the trailing edge. As a result, film thickness may be uneven across one or more edge regions of the substrate. This film non-uniformity may cause lithography issues and may lead to a loss in die yield from a given substrate.

Thus, there is a need for improved systems and methods that can be used to polish substrates to generate a uniform film across an entire surface area of the substrate. These and other needs are addressed by the present technology.

### SUMMARY

Exemplary carrier heads for a chemical mechanical polishing apparatus may include a carrier body. The carrier heads may include a substrate mounting surface coupled with the carrier body. The carrier heads may include an inner ring that is sized and shaped to circumferentially surround a peripheral edge of a substrate positioned against the substrate mounting surface. The inner ring may be characterized by a first end having a first surface that faces the carrier body and a second end having a second surface opposite the first surface. The second end of the inner ring may be radially displaceable. The carrier heads may include an outer ring having an inner surface that is disposed against an outer surface of the inner ring.

In some embodiments, the inner ring may define a plurality of grooves through the second surface, with each of the plurality of grooves extending through a portion of a height of the inner ring. The inner ring may define a plurality of slits. Each of the plurality of slits may extend through a top surface of a respective one of the plurality of grooves and may extend through an additional portion of the height of the inner ring. A height of each of the plurality of slits may be between about 0.25 inches and 1 inch. The plurality of slits may be spaced at regular intervals about a circumference of the inner ring. The plurality of slits may be angularly offset from radial lines extending from a center of the inner ring. The plurality of slits may include at least 9 slits. An inner surface of the outer ring may include scalloping. The scalloping may include a first inner radius and a second inner radius. A difference between the first inner radius and the second inner radius may be between about 0.05 mm and 2 mm. A bottom surface of a contact member of the outer ring may be elevated relative to the second surface of the inner ring. A vertical distance between the bottom surface of the contact member of the outer ring and the second surface of the inner ring may be between about 0.25 mm and 2 mm.

Some embodiments of the present technology may encompass inner retaining rings for a chemical mechanical polishing apparatus. The inner retaining rings may include an annular body that is characterized by a first surface, a second surface opposite the first surface, an outer surface that extends between and couples the first surface and the second surface, and an inner surface that extends between and couples the first surface and the second surface. The annular body may define a plurality of grooves through the second surface, with each of the plurality of grooves extending through a portion of a height of the inner ring. The annular body may define a plurality of slits that extend through the inner surface and the outer surface and that enable a lower end of the annular body to be radially displaceable.

In some embodiments, each slit may have a width that is less than a width of each of the plurality of grooves. Each of the plurality of slits may extend through a top surface of a respective one of the plurality of grooves and may extend through an additional portion of the height of the annular body. A number of the plurality of slits may be equal to a number of the plurality of grooves. A height of each of the plurality of slits may be greater than a height of each of the plurality of grooves. Each of the plurality of slits may be angled in a direction of rotation of the annular body with respect to a respective radial line extending from a center of the annular body. The plurality of slits may include between about 9 slits and 90 slits.

Some embodiments of the present technology may encompass methods of polishing a substrate. The methods may include flowing a polishing slurry from a slurry source to a polishing pad. The methods may include polishing a substrate atop the polishing pad. The methods may include radially displacing at least a portion of a lower end of an inner ring that retains the substrate within a carrier head while polishing the substrate.

In some embodiments, radially displacing at least a portion of the lower end of the inner ring may include displacing one or more islands of a plurality of islands in a radially outward direction. The plurality of islands may be arranged about a circumference of the inner ring and may be separated from one another by a plurality of slits defined within the inner ring. An outer ring having an inner surface may be disposed against an outer surface of the inner ring. The inner surface of the outer ring may include scalloping. The scalloping may include an undulating pattern of regions having a first inner radius and regions having a larger second inner radius such that pockets are formed within each region having the second inner radius. Radially displacing at least a portion of the lower end of the inner ring may include deforming a portion of the inner ring into at least one of the pockets.

Such technology may provide numerous benefits over conventional systems and techniques. For example, the polishing heads and retaining rings described herein may help prevent excess polishing from occurring at the edge regions, and in particular at the trailing edge, of a substrate during polishing operations. This may enable the film thickness uniformity to be improved across the surface of the substrate, which may lead to increased die yield. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary polishing system according to some embodiments of the present technology.

FIG. 2 shows a schematic partial cross-sectional view of an exemplary carrier head according to some embodiments of the present technology.

FIG. 3 shows a schematic isometric view of an exemplary inner ring according to some embodiments of the present technology.

FIG. 3A shows a schematic partial cross-sectional side elevation view of the inner ring of FIG. 3.

FIG. 3B shows a cross-sectional schematic top plan view of the inner ring of FIG. 3.

FIG. 4 shows a schematic partial cross-sectional side elevation view of an exemplary polishing system according to some embodiments of the present technology.

FIG. 5 shows a schematic partial cross-sectional top plan view of an exemplary outer ring according to some embodiments of the present technology.

FIG. 6 is a flowchart of an exemplary method of polishing a substrate according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In conventional chemical mechanical polishing (CMP) operations it is often difficult to uniformly polish the surface of a substrate. Conventional CMP polishing involves a substrate being positioned face down on a polishing pad, with a carrier that holds the substrate against a rotating polishing pad. As the substrate and polishing pad are moved relative to one another, the trailing edge of the substrate may be pushed against an inner surface of an inner retaining ring. In conventional CMP systems, the contact between the inner retaining ring and the trailing edge of the substrate generates a side load that increases stress on the substrate near the trailing edge. This increased substrate stress causes increased polishing/material removal rates at and/or proximate the trailing edge relative to the rest of the substrate. This may result in film non-uniformity issues that result in a lower die yield.

The present technology overcomes these issues with conventional polishing systems by incorporating a design of an inner and/or outer retaining ring of the carrier head that enables the inner retaining ring to deform and/or deflect radially outward upon being contacted by the substrate during polishing operations. Enabling the inner retaining ring to deform and/or deflect radially outward may increase the contact area between the inner retaining ring and the substrate may be increased, which may enable the side load caused by the contact between the inner retaining ring and the substrate to be distributed over a larger area. This in turn may reduce the pressure and subsequent stresses experienced by the trailing edge of the substrate, which may help reduce any uneven polishing rates across the surface of the substrate. These techniques may be used in conjunction with conventional CMP systems to produce substrates with improved film thickness uniformity.

Although the remaining disclosure will routinely identify specific film polishing processes utilizing the disclosed technology, it will be readily understood that the systems and methods are equally applicable to a variety of other semiconductor processing operations and systems. Accordingly, the technology should not be considered to be so limited as for use with the described polishing systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

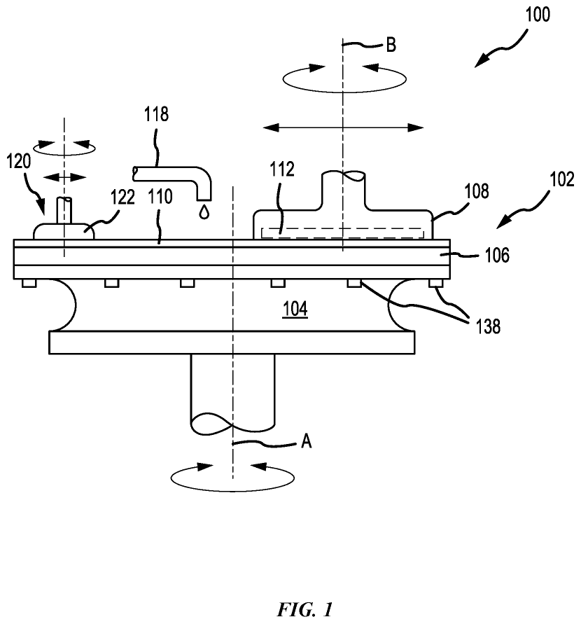

FIG. 1 shows a schematic cross-sectional view of an exemplary polishing system 100 according to some embodiments of the present technology. Polishing system 100 includes a platen assembly 102, which includes a lower platen 104 and an upper platen 106. Lower platen 104 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 104, and which may access upper platen 106 through a backside of the upper platen. Platen assembly 102 may include a polishing pad 110 mounted on a first surface of the upper platen. A substrate carrier 108, or carrier head, may be disposed above the polishing pad 110 and may face the polishing pad 110. The platen assembly 102 may be rotatable about an axis A, while the substrate carrier 108 may be rotatable about an axis B. The substrate carrier may also be configured to sweep back and forth from an inner radius to an outer radius along the platen assembly, which may, in part, reduce uneven wear of the surface of the polishing pad 110. The polishing system 100 may also include a fluid delivery arm 118 positioned above the polishing pad 110, and which may be used to deliver polishing fluids, such as a polishing slurry, onto the polishing pad 110. Additionally, a pad conditioning assembly 120 may be disposed above the polishing pad 110, and may face the polishing pad 110.

In some embodiments of performing a chemical-mechanical polishing process, the rotating and/or sweeping substrate carrier 108 may exert a downforce against a substrate 112, which is shown in phantom and may be disposed within or coupled with the substrate carrier. The downward force applied may depress a material surface of the substrate 112 against the polishing pad 110 as the polishing pad 110 rotates about a central axis of the platen assembly. The interaction of the substrate 112 against the polishing pad 110 may occur in the presence of one or more polishing fluids delivered by the fluid delivery arm 118. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 112.

The pad conditioning assembly 120 may be operated to apply a fixed abrasive conditioning disk 122 against the surface of the polishing pad 110, which may be rotated as previously noted. The conditioning disk may be operated against the pad prior to, subsequent, or during polishing of the substrate 112. Conditioning the polishing pad 110 with the conditioning disk 122 may maintain the polishing pad 110 in a desired condition by abrading, rejuvenating, and removing polish byproducts and other debris from the polishing surface of the polishing pad 110. Upper platen 106 may be disposed on a mounting surface of the lower platen 104, and may be coupled with the lower platen 104 using a plurality of fasteners 138, such as extending through an annular flange shaped portion of the lower platen 104.

The polishing platen assembly 102, and thus the upper platen 106, may be suitably sized for any desired polishing system, and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for a polishing platen 106 sized for concurrent polishing of multiple substrates. The upper platen 106 may be characterized by a thickness of between about 20 mm and about 150 mm, and may be characterized by a thickness of less than or about 100 mm, such as less than or about 80 mm, less than or about 60 mm, less than or about 40 mm, or less. In some embodiments, a ratio of a diameter to a thickness of the polishing platen 106 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, light-weight, and polishing fluid corrosion-resistant material, such as aluminum, an aluminum alloy, or stainless steel, although any number of materials may be used. Polishing pad 110 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 100 is included to provide suitable reference to components discussed below, which may be incorporated in system 100, although the description of polishing system 100 is not intended to limit the present technology in any way, as embodiments of the present technology may be incorporated in any number of polishing systems that may benefit from the components and/or capabilities as described further below.

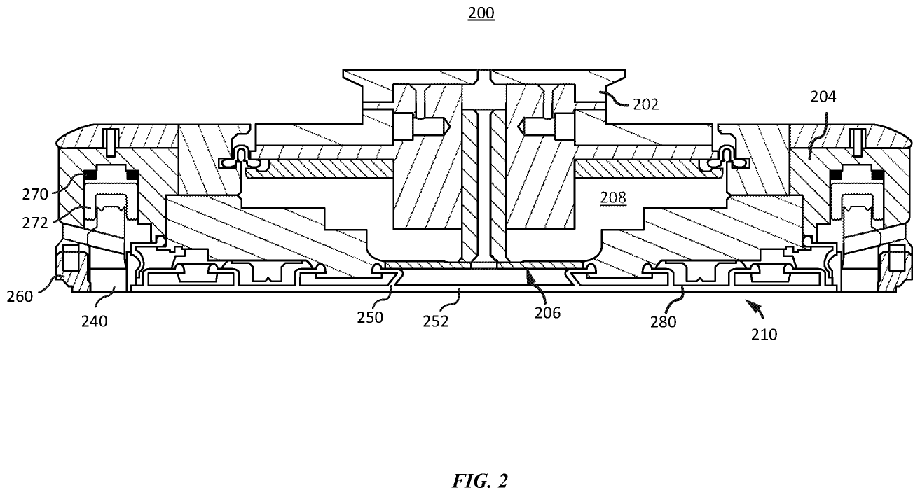

FIG. 2 illustrates a schematic cross-sectional side elevation view of an exemplary carrier head 200 according to some embodiments of the present technology. The carrier head 200 may show a partial view of the components being discussed and that may be incorporated in a polishing system, similar to polishing system 100. The carrier head 200 may be used as substrate carrier 108 in some embodiments. Carrier head 200 may include a housing 202, a base assembly 204 (housing 202 and base assembly 204 may be referred to as a carrier body), a gimbal mechanism 206 (which may be considered part of the base assembly 204), a loading chamber 208, an inner ring assembly including an inner ring 240 and a first flexible membrane 270 shaped to provide an annular chamber 272, an outer ring 260, and a substrate backing assembly 210, which may include a second flexible membrane 250 that defines a plurality of pressurizable chambers.

The housing 202 may generally be circular in shape and may be connected to a drive shaft to rotate therewith during polishing. There may be passages (not illustrated) extending through the housing 202 for pneumatic control of the carrier head 200. The base assembly 204 may be a vertically movable assembly located beneath the housing 202. The gimbal mechanism 206 may permit the base assembly 204 to gimbal relative to the housing 202, while preventing lateral motion of the base assembly 204 relative to the housing 202. The loading chamber 208 may be located between the housing 202 and the base assembly 204 to apply a load, i.e., a downward pressure or weight, to the base assembly 204. The vertical position of the base assembly 204 relative to a polishing pad (such as polishing pad 110) may be also controlled by the loading chamber 208. The substrate backing assembly 210 may include a flexible membrane 250 with a lower surface 252 that may provide a mounting surface for a substrate 280.

The substrate 280 can be held by the inner ring assembly, which may be clamped to a base assembly 204. The inner ring assembly may be constructed from inner ring 240 and a flexible membrane 250 shaped to provide an annular chamber. The inner ring 240 may be positioned beneath the flexible membrane 250 and may be configured to be secured to the flexible membrane 250. While the inner ring 240 may be configured to retain substrate 280 and provide active edge process control, the outer ring 260 may provide positioning or referencing of the carrier head 200 to the surface of the polishing pad. In addition, the outer ring 260 may contact and provide lateral referencing of the inner ring 240. The outer ring 260 may circumferentially surround inner ring 240 and may include an inner surface that is disposed against the outer surface of the inner ring 240. Like the inner ring 240, a lower surface of the outer ring 260 may be brought into contact with the polishing pad. The lower surface of the outer ring 260 may be smooth and wearable surface and may be selected so as to not abrade the polishing pad. An upper surface of the outer ring 260 may be secured to the base 204, e.g., the outer ring 260 may not vertically movable relative to the base 204. In some embodiments, an upper portion of the outer ring 260 may be formed of a material that is more rigid than a lower portion of the outer ring 260. For example, the lower portion may be a plastic, e.g., polyetheretherketone (PEEK), carbon filled PEEK, Teflon® filled PEEK, polyamideimide (PAI), or a composite material, while the upper portion may be a metal, e.g., stainless steel, molybdenum, or aluminum, or a ceramic, e.g., alumina. A portion of the outer ring 260 that includes the lower surface may be formed of a more rigid material than the portion of the inner ring 240 that includes the second surface 246. This may result in the outer ring 260 wearing at a lower rate than the inner ring 240. For example, the lower portion of the outer ring 260 may be a plastic that is harder than the plastic of the inner ring 240.

The flexible membrane 250 may be configured to be clamped above to base assembly 204 and secured below to inner ring 240. Positioning the flexible membrane between the inner ring 240 and the carrier head 200 may reduce or eliminate the impact of carrier distortion on the inner ring 240 which occurs when the ring 240 is directly secured to the carrier head 200. The elimination of this carrier distortion may reduce the uneven wear on the inner ring 240, reduce process variability at the substrate edge, and enable lower polishing pressures to be used, increasing ring lifetime. The flexible membrane 250 may be formed of a material that is elastic, allowing the membrane to flex under pressure. The elastic material may include silicone and other exemplary materials.

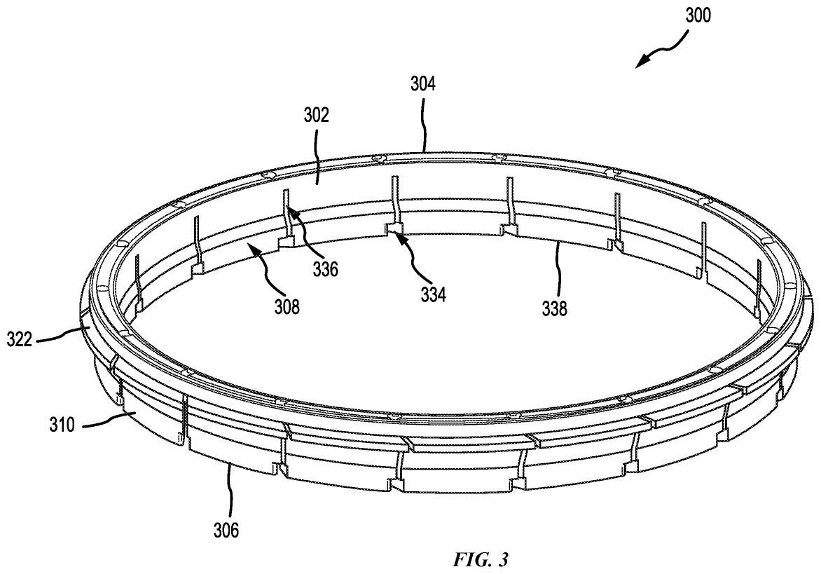

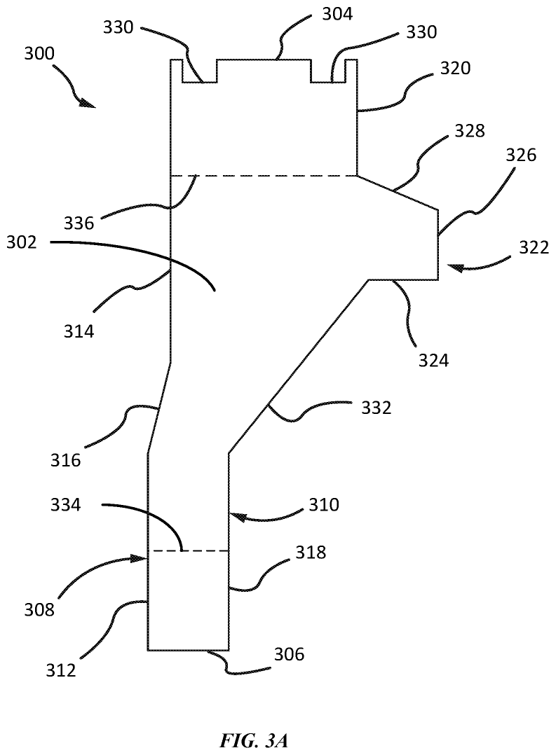

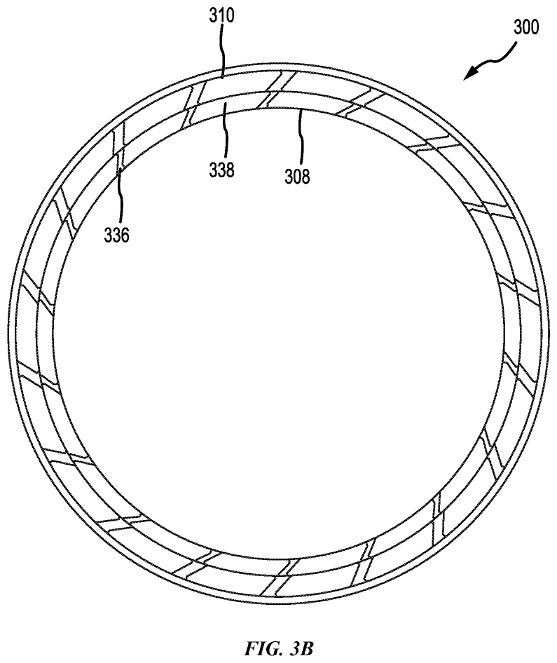

As described above in conjunction with FIGS. 3-5 below, in some embodiments, the inner ring and/or the outer ring may include one or more features that enable the lower end of the inner ring to be radially displaceable. In particular, the features enable the lower end of the inner ring to be radially displaceable in an outward direction when contacted by the trailing edge (or other edge region) of the substrate during polishing operations. The radially displaceable inner ring may help distribute contact forces between the substrate and the inner ring over a greater area of the substrate, which may help eliminate polishing hot spots that have higher removal rates, which if uncorrected, may cause low film thickness along the affected region of the edge of the substrate.

FIG. 3 illustrates a schematic isometric view of an exemplary inner retaining ring or inner ring 300 according to some embodiments of the present technology. The inner ring 300 may be used to perform substrate polishing operations. FIG. 3 may show a partial view of the components being discussed and that may be incorporated in a chemical mechanical polishing system, such as polishing system 100 described herein. Inner ring 300 may be used as inner ring 240 and may be used in a carrier head, such as carrier head 108 and/or carrier head 200 in some embodiments. Inner ring 300 may be understood to include any feature described in relation to inner ring 240. Inner ring 300 may include an annular body 302 that may be characterized by a first surface 304 (e.g., an upper surface) that faces a carrier body and a second surface 306 (e.g., a lower surface) opposite the first surface 304. Inner surface 308 and outer surface 310 may oppose one another and may each extend between and couple the first surface 304 and the second surface 306. The annular body 302 may be sized and shaped to circumferentially surround a peripheral edge of a substrate positioned against the substrate mounting surface 304. For example, a lowermost end (proximate the second surface 306) of the inner ring 300 may have an inner diameter that is greater than a diameter of a substrate being polished by a small amount (e.g., less than or about 5 mm, less than or about 4 mm, less than or about 3 mm, less than or about 2 mm, less than or about 1 mm, less than or about 0.5 mm, or less) such that the inner ring 300 may serve as a retaining ring to keep the substrate from sliding out of engagement with the substrate mounting surface (e.g., flexible membrane) during polishing operations.

The second surface 306 may be brought into contact with the polishing pad (and abrasive slurry) while polishing the substrate. The second surface 306 may be formed of a material which is chemically inert in a CMP process, such as a plastic, e.g., polyphenylene sulfide (PPS), polyether ether ketone (PEEK), polyethylene terephthalate (PET), and/or other polymer. The inner ring 300 may be substantially rigid in a vertical direction (e.g., a direction that extends through the first surface 304 and the second surface 306) and/or horizontal direction, or may have some degree of flexibility (e.g., compressibility) in the vertical direction and/or the horizontal direction.

As best illustrated in FIG. 3A, a lower region 312 of the inner surface 308, adjacent to the second surface 306, may be a generally vertical cylindrical surface, and may be configured to circumferentially surround the edge of a substrate to retain the substrate during polishing. The lower region 312 of the inner surface 308 may have an inner diameter just larger than the substrate diameter, e.g., about 1-2 mm larger than the substrate diameter, so as to accommodate positioning tolerances of the substrate loading system. An upper region 314 of the inner surface 308 may be a generally vertical cylindrical surface, and may be slightly recessed relative to the lower region 312, e.g., the inner radial diameter of the upper region 314 of the inner surface 308 may be greater than the inner radial diameter of the lower region 312 of the inner surface 308. A tapered region 316 may connect the lower region 312 to the upper region 314 in some embodiments.

A lower region 318 of the outer surface 310, adjacent to the second surface 306, may be a vertical cylindrical surface. The portion of the inner ring 300 between the lower region 312 of the inner surface 306 and the lower region 318 of the outer surface 310 may provide a lower annular ring, e.g., with a width of 0.04 to 0.20 inches, e.g., 0.05 to 0.15 inches. An upper region 320 of the outer surface 310, adjacent to the first surface 304, may be a vertical cylindrical surface, and the lower region 318 of the outer surface 310 may be recessed relative to the upper region 320, e.g., the outer radial diameter of the upper region 320 may be greater than the outer radial diameter of the lower region 318 of the outer surface 310. The portion of the inner ring 300 between the upper region 314 of the inner surface 308 and the upper region 320 of the outer surface 310 may provide an upper annular ring that is wider than the lower annular ring. The outer radial diameter of the lower ring (i.e., the lower region 318 of the outer surface 310) may be greater than the inner radial diameter of the upper ring (i.e., the upper region 314 of the inner surface 308).

The outer surface 310 of the inner ring 300 may project outwardly to form a lip 322 between the lower region 318 and the upper region 320. The lip 322 may have a horizontal lower surface 324, a vertical outer surface 326, and a sloping, non-horizontal upper surface 328. The lip 322 may provide a hard stop for the inner ring 300 against a top inner edge of an outer ring (such as outer ring 260) as the inner ring 300 wears during substrate polishing. The annular first surface 304 may have one or more annular concentric recesses 330 that extend entirely around the annular inner ring 300. These annular concentric recesses 330 may be sized to interlock with a flexible membrane (such as flexible membrane 270) in some embodiments. A sloped area 332 of the outer surface 310 may connect the lower region 318 to the horizontal lower surface 324 of the lip 322.

The second surface 306 of the inner ring 300 may be brought into contact with a polishing pad. At least a lower portion of the inner ring 300 that includes the second surface 306 may be formed of a material which is chemically inert in a CMP process, such as a plastic, e.g., polyphenylene sulfide (PPS). The lower portion should also be durable and have a low wear rate. In addition, the lower portion should be sufficiently compressible so that contact of the substrate edge against the inner ring does not cause the substrate to chip or crack. On the other hand, the lower portion should not be so elastic that downward pressure on the inner ring 300 causes the lower portion to extrude into the substrate receiving recess. In some embodiments, the upper portion of the inner ring 300 may be formed of a material that is more rigid than the lower portion. For example, the lower portion may be a plastic, e.g., PPS, and the upper portion may be a metal, e.g., stainless steel, molybdenum, or aluminum, or a ceramic, e.g., alumina.

In some implementations, the inner ring 300 may have one or more through holes that extend through the body of the inner ring 300 from the inner surface 308 to the outer surface 310 for allowing fluid, e.g., air or water, to pass from the interior to the exterior, or from the exterior to the interior, of the inner ring 300 during polishing. The through-holes may extend through the upper ring. The through holes may be evenly spaced around the inner ring 300 in some embodiments.

In some implementations the upper portion of the inner ring 300 may be wider at the lower surface than the upper surface. For example, the inner surface 308 may have a tapered region that slopes inwardly (i.e., having decreasing diameter) from top to bottom below a vertical region. The inner surface of the lower portion may be generally vertical. As the lower portion of the inner ring 300 wears during substrate polishing, the narrower upper inner surface of the inner ring 300 may prevent wear on an adjacent flexible membrane (such as flexible membrane 250) that provides a substrate-mounting surface. In addition, in some implementations, the entire outer surface 310 of the inner ring 300 may be coated with a non-stick coating, e.g., parylene.

As best illustrated in FIG. 3, the inner ring 300 may define a plurality of grooves 334 through the second surface 306. Each groove 334 may extend upward from the second surface 306 through a portion of a height of the inner ring 300, and may terminate prior to reaching the first surface 304. The grooves 334 may enable slurry to pass through to an interior of the inner ring 300 and to the substrate constrained within the inner ring 300 during polishing operations. For example, the grooves 334 may extend from the inner surface 306 to the outer surface 308 of the lower ring portion to allow slurry to pass from the exterior to the interior of the inner ring 300 during polishing. The grooves 334 may be evenly spaced around the inner ring 300 in some embodiments. Each groove 334 may be offset at an angle relative to radial lines extending from a center of the inner ring 300 and through a respective one of the grooves 334. For example, each groove 334 may be angled relative to a corresponding radial line by between or about 10 degrees and 80 degrees, between or about 20 degrees and 70 degrees, between or about 30 degrees and 60 degrees, between or about 40 degrees and 50 degrees, or about 45 degrees. In some embodiments, the grooves 334 may be angled in a direction of rotation of the carrier head such that the grooves 334 may enable slurry to be scooped or otherwise directed into an interior of the inner ring 300 as the carrier head and polishing pad are rotated relative to one another. Each groove 334 may have a width of between or about 0.05 inches and 0.5 inches, between or about 0.075 inches and 0.4 inches, between or about 0.1 inches and 0.3 inches, or between or about 0.125 inches and 0.2 inches. Each groove 334 may have a height of between or about 0.05 inches and 0.5 inches, between or about 0.075 inches and 0.4 inches, between or about 0.1 inches and 0.3 inches, or between or about 0.125 inches and 0.2 inches. For example, in some embodiments, each groove 334 may extend through a portion of lower regions 312, 318 and may terminate prior to reaching the tapered region 316 and/or sloped area 332.

The inner ring 300 may define a plurality of slits 336, with each slit 336 extending from the second surface 306 of the inner ring 300. In some embodiments, each slit 336 may extend through a top surface of a respective one of the grooves 334 and may extend through an additional portion of the height of the inner ring 300. As illustrated, each slit 336 may extend upward from the second surface 306 and/or the top surface of a respective groove 334 and through a portion of a height of the inner ring 300, and may terminate prior to reaching the first surface 308. Adjacent slits 336 may define separate flaps, or islands 338, of the inner ring 300 that are movable independently of one another. The slits 336 may enable a lower end of the inner ring 300 (such as, but not limited to, lower regions 312, 318) to be radially displaced when inner surface 308 is contacted by an edge (such as the trailing edge) of the substrate during polishing operations. For example, lower ends of one or more of the islands 338 may be radially displaced in an outward direction when contacted by the substrate. The displacement of the inner surface 306 of the inner ring 300 may enable the contact forces between the substrate and the inner ring 300 to be distributed over a larger area, which may reduce the side load on the substrate and reduce polishing rates along the edge (e.g., trailing edge) of the substrate to improve polishing uniformity.

The slits 336 may be evenly spaced around the inner ring 300 in some embodiments. For example, each slit 336 may be aligned with a respective one of the grooves 334 such that a number of slits 336 may be equal to a number of grooves 334. In a particular embodiment, there may be between about 9 slits 336 and 360 slits 336, between 9 slits and 270 slits, between 9 slits and 240 slits, between 9 slits and 210 slits, between 9 slits and 180 slits, between 9 slits and 150 slits, between 9 slits and 120 slits, or between 9 slits and 90 slits spaced apart about the inner ring 300, typically at regular intervals. For example, the inner ring 300 may include at least or about 9 slits, at least or about 18 slits, at least or about 36 slits, at least or about 54 slits, at least or about 72 slits, at least or about 90 slits, at least or about 120 slits, at least or about 150 slits, at least or about 180 slits, at least or about 210 slits, at least or about 240 slits, at least or about 270 slits, at least or about 300 slits, at least or about 330 slits, at least or about 360 slits, or more, with greater numbers of slits reducing the amount of force needed to radially displace a respective portion (e.g., island 338) of the inner ring 300. As best illustrated in FIG. 3B, in some embodiments, each slit 336 may be offset at an angle relative to radial lines extending from a center of the inner ring 300 and through a respective one of the slits 336. For example, each slit 336 may be angled relative to a corresponding radial line by between or about 10 degrees and 80 degrees, between or about 20 degrees and 70 degrees, between or about 30 degrees and 60 degrees, between or about 40 degrees and 50 degrees, or about 45 degrees. In some embodiments, the slits 336 may be aligned with a corresponding groove 334, with each paired slit 336 and groove 334 being offset at a same angle relative to a corresponding radial line. In some embodiments, the grooves 334 and/or slits 336 may be aligned with (e.g., coaxial) corresponding radial lines, rather than being angled.

In some embodiments, each slit 336 may be thinner than a respective groove 334. For example, each slit 336 may have a width of between or about 0.01 inches and 0.5 inches, between or about 0.025 inches and 0.4 inches, between or about 0.05 inches and 0.3 inches, between or about 0.075 inches and 0.2 inches, or between or about 0.1 and 0.15 inches. When measured from the second surface 306, each slit 336 may have a height of between or about 0.3 inches and 1.5 inches, between or about 0.325 inches and 1.4 inches, between or about 0.35 inches and 1.3 inches, or between or about 0.375 inches and 1.2 inches. When measured from the top surface of a respective groove 334, each slit 336 may have a height of between or about 0.25 inches and 1 inch, between or about 0.3 inches and 0.95 inches, between or about 0.35 inches and 0.9 inches, between or about 0.4 inches and 0.85 inches, between or about 0.45 inches and 0.8 inches, between or about 0.5 inches and 0.75 inches, between or about 0.55 inches and 0.7 inches, or between or about 0.6 inches and 0.65 inches, although other heights are possible in some embodiments, with greater heights reducing the amount of force needed to displace a given island 338. In some embodiments, each slit 336 may extend through all or a portion of lower regions 312, 318, the tapered region 316, sloped area 332, upper portion 314, and/or lip 322. As illustrated, the slits 336 may each terminate at or proximate a junction of the lip 322 and the upper region 320 of the inner ring 300.

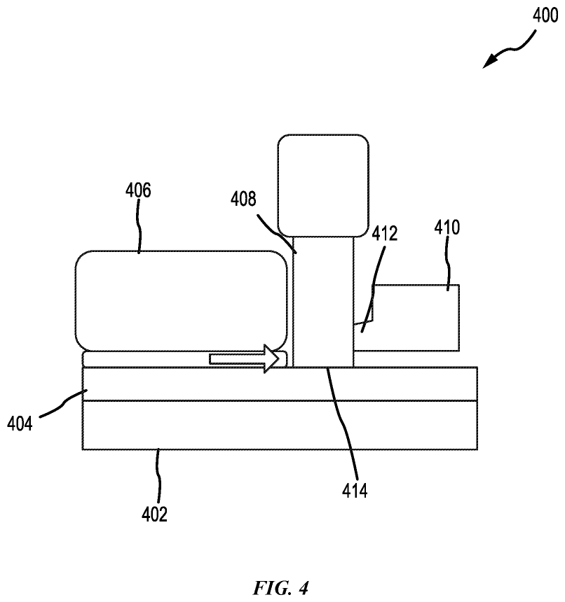

FIG. 4 illustrates a partial sectional schematic side elevation view of an exemplary polishing system 400 according to some embodiments of the present technology. The polishing system 400 may be used to perform substrate polishing operations. FIG. 4 may show a partial view of the components being discussed and that may be incorporated in a chemical mechanical polishing system, such as polishing system 400 described herein. Polishing system 400 may include a platen 402 (which may be similar to upper platen 106), a polishing pad 404 (which m may be similar to polishing pad 110) disposed atop the platen 402, a flexible membrane 406 for contacting a substrate 450, an inner ring 408 (which may be similar to inner ring 240 and/or 300) of a carrier head (not shown), and an outer ring 410 (which may be similar to outer ring 260). Inner ring 408 may be understood to include any feature described in relation to inner ring 240 or 300. An inner surface of the outer ring 410 may include a contact member 412 that may, in some embodiments, may protrude inward toward the inner ring 408. In other embodiments, the contact member 412 may just be the inner surface of the outer ring 410. In some embodiments, the contact member 412 is disposed at the bottom of the outer ring 410, while in other embodiments the contact member 412 may be raised relative to the bottom surface of the outer ring 410. A bottom surface of the contact member 412 (and possibly the outer ring 410) may be elevated relative to a second surface 414 (i.e., bottom surface) of the inner ring 408. For example, the bottom surface of the contact member 412 may be elevated by between or about 0.25 mm and 2 mm, between or about 0.35 mm and 1.75 mm, between or about 0.5 mm and 1.5 mm, or between or about 0.75 mm and 1.25 mm, although greater elevation heights are possible in some embodiments. In some embodiments, a vertical distance between the second surface 414 of the inner ring 408 and the bottom surface of the contact member 412 may be based on a thickness of the substrate 450. For example, the vertical distance may be at least or about 0.25× the thickness of the substrate 450, at least or about 0.5× the thickness, at least or about 0.75× the thickness, at least or about 1× the thickness, at least or about 1.25× the thickness, at least or about 1.5× the thickness, at least or about 1.75× the thickness, at least or about 2× the thickness, or more. The vertical offset between the bottom surface of the contact member 412 and the second surface 414 of the inner ring 408 may create a deflection point that enables the inner ring 408 to be radially displaceable in an outward direction when the lower end of the inner ring 408 is contacted by an edge of the substrate 450, with higher amounts of vertical offset enabling greater displacement of the lower portion of the inner ring 408 and enabling lower amounts of contact force between the substrate 450 and the inner ring 408 to displace the lower portion of the inner ring 408. The displacement of the lower portion of the inner ring 408 may enable the contact forces between the substrate 450 and the inner ring 408 to be distributed over a larger area, which may reduce the side load on the substrate 450 and reduce polishing rates along the edge (e.g., trailing edge) of the substrate 450 to improve polishing uniformity.

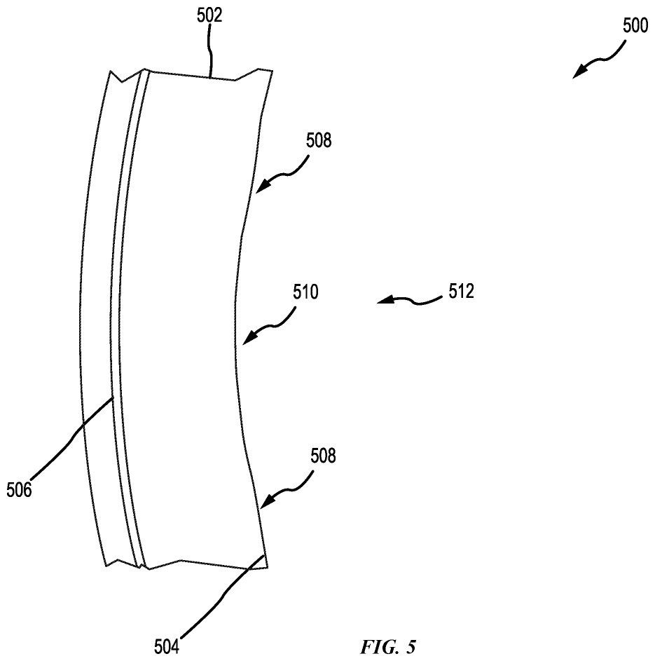

FIG. 5 illustrates a partial schematic top plan view of an exemplary outer retaining ring or outer ring 500 according to some embodiments of the present technology. The outer ring 500 may be used to perform substrate polishing operations. FIG. 5 may show a partial view of the components being discussed and that may be incorporated in a chemical mechanical polishing system, such as polishing system 100 described herein. Outer ring 500 may be used as outer ring 260 and/or 410 and may be used in a carrier head, such as carrier head 108 and/or carrier head 200 in some embodiments. Outer ring 500 may be understood to include any feature described in relation to outer ring 260 and/or 410. Outer ring 500 may include an annular body 502 that may be characterized by an inner surface 504 that faces an inner ring (such as inner ring 240, 300, and/or 408) and a substrate, and an outer surface 506 opposite the inner surface 504. The inner surface 504 may include scalloping in some embodiments. For example, the inner surface 504 may be characterized by two or more inner radii. As illustrated, the inner surface 504 may be characterized by regions 508 having a first inner radius that are interleaved with regions 510 having a second, larger inner radius. This forms alternating regions having bigger and smaller radii such that pockets 512 are formed in a region 510 surrounded by a region 508 on either side. These pockets 512 may provide an area in which a portion of the inner ring (such as inner ring 240, 300, and/or 408) may be deformed and/or otherwise displaced into when contacted by an edge of the substrate being polished. For example, in a neutral position portions of the inner ring contacting the regions 508 having the smaller radius may be constrained from outward movement, while portions of the inner ring proximate the regions 510 (with larger radii) may be spaced apart from the inner surface 504 of the outer ring 500. As the inner ring is contacted by the substrate, portions of the inner ring proximate the regions 510 may deflect into the pockets 512, which may enable deformation of the inner ring that spreads the contact between the substrate and the inner ring along a larger arc/area of the inner ring, and subsequently reduces the side load on the substrate to reduce polishing rates along the edge (e.g., trailing edge) of the substrate to improve polishing uniformity.

In some embodiments, the difference between the first radius and the second radius may be between or about 0.05 mm and 2 mm, between or about 0.25 and 1.75 mm, between or about 0.5 mm and 1.5 mm, between or about 0.75 mm and 1.25 mm, or about 1 mm. Regions 508 and 510 may alternate at regular intervals about the circumference of the outer ring 500. For example, the regions 508, 510 may alternate at regular intervals of at least or about 5 degrees, at least or about 10 degrees, at least or about 15 degrees, at least or about 20 degrees, at least or about 30 degrees, at least or about 45 degrees, or more. In some embodiments, the regions 508, 510 may be arranged such that a pocket 512 is located proximate areas that are most likely to correspond to high polishing rates, such as at or proximate the trailing edge of the substrate. This may ensure that the pockets 512 are capable of receiving deflected or otherwise displaced portions of the inner ring near trouble areas of the substrate.

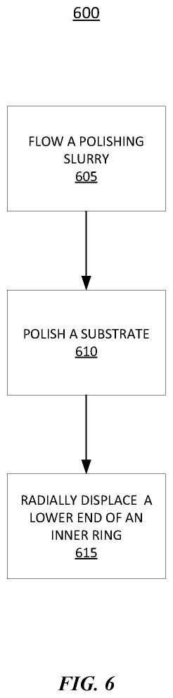

FIG. 6 shows exemplary operations in a method 600 for polishing a substrate according to some embodiments of the present technology. Method 600 may be performed using carrier head (such as carrier head 108), inner ring (such as inner ring 240, 300, 408), and/or an outer ring (such as outer ring 260, 408, 500) described herein. Method 600 may include operations prior to the substrate polishing in some embodiments. For example, prior to the polishing, a substrate may have one or more deposition and/or etching operations performed as well as any planarization or other process operations performed. Method 600 may include a number of operations that may be performed automatically within a system to limit manual interaction, and to provide increased efficiency and precision over manual operations. Method 600 may be performed as part of or in conjunction with a conventional CMP polishing process.

Method 600 may include flowing a polishing slurry from a slurry source to a polishing pad at operation 605. The substrate may be polished atop the polishing pad at operation 610. For example, the substrate may be positioned within a carrier head that rotates and/or translates (or sweeps) the substrate about the surface of the polishing pad such that abrasive particles within the polishing slurry may gradually remove material from a surface of the substrate in a desired pattern and/or to achieve a desired film thickness profile. In some embodiments, in addition to or alternatively to the carrier head rotating and/or translating, the polishing pad may rotate and/or translate. A back surface of the substrate may be positioned against a substrate mounting surface, such as a flexible membrane, of the carrier head that may be used to apply pressure to the back surface of the substrate during polishing operations. The substrate may be retained in a desired position relative to the carrier head and flexible membrane using an inner ring that is disposed radially outward of the substrate. To counteract uneven polishing rates that may occur due to the side loads that may develop as the substrate contacts an inner surface of inner ring as the carrier head and polishing pad are moved relative to one another, at least a portion of a lower end of the inner ring may be radially displaced at operation 615. The displacement may be in a radially outward direction and may distribute contact forces between the substrate and the inner ring over a larger area, which may reduce the side load on the substrate and reduce polishing rates along the edge (e.g., trailing edge) of the substrate to improve polishing uniformity. Displacement of the inner ring (or portion thereof) may be on the order of microns in some embodiments, although in other instances the deformation and/or other radial displacement of the inner ring (or portion thereof) may be up to several millimeters.

In some embodiments, radially displacing the portion of the inner ring may include displacing one or more islands of the inner ring in a radially outward direction. The islands may be arranged about a circumference of the inner ring and may be separated from one another by a number of grooves (such as grooves 334) and/or slits (such as slits 336) defined within the inner ring. In some embodiments, radially displacing the portion of the inner ring may include displacing a lower end of the inner ring that is lower than a bottom surface of a contact member (such as contact member 412) of an outer ring disposed against an outer surface of the inner ring. The contact member may create a deflection point that enables the lower end of the inner ring to flex outward when contacted by the substrate. In some embodiments, radially displacing the portion of the inner ring may include deforming a portion of the inner ring into at least one pocket (such as pocket 512) formed in an inner surface of the outer ring. For example, the inner surface of the outer ring may include scalloping that includes an alternating/undulating pattern of regions having a first inner radius and regions having a larger second inner radius such that pockets are formed within each region having the second inner radius. Other techniques of radially displacing a portion of the inner ring may be utilized in various embodiments. It will be appreciated that in some embodiments multiple forms (including techniques not explicitly disclosed herein, such as by using a softer, radially compressible inner ring) of radially displacing the portion of the inner ring may be combined. For example, the inner ring may include slits, a bottom surface of the outer ring (and/or a contact member thereof) may be elevated relative to a bottom surface of the inner ring, an inner surface of the outer ring may include scalloping, and/or other techniques may be implemented in a single embodiment.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A carrier head for a chemical mechanical polishing apparatus, comprising:
a carrier body;
a substrate mounting surface coupled with the carrier body;
an inner ring that is sized and shaped to circumferentially surround a peripheral edge of a substrate positioned against the substrate mounting surface, the inner ring being characterized by a first end having a first surface that faces the carrier body and a second end having a second surface opposite the first surface, wherein the second end of the inner ring is radially displaceable; and
an outer ring having an inner surface that is disposed against an outer surface of the inner ring.

2. The carrier head for a chemical mechanism polishing apparatus of claim 1, wherein:
the inner ring defines a plurality of grooves through the second surface, with each of the plurality of grooves extending through a portion of a height of the inner ring; and
the inner ring defines a plurality of slits, wherein each of the plurality of slits extends through a top surface of a respective one of the plurality of grooves and extends through an additional portion of the height of the inner ring.

3. The carrier head for a chemical mechanical polishing apparatus of claim 2, wherein:
a height of each of the plurality of slits is between about 0.25 inches and 1 inch.

4. The carrier head for a chemical mechanical polishing apparatus of claim 2, wherein:
the plurality of slits are spaced at regular intervals about a circumference of the inner ring.

5. The carrier head for a chemical mechanical polishing apparatus of claim 2, wherein:
the plurality of slits are angularly offset from radial lines extending from a center of the inner ring.

6. The carrier head for a chemical mechanical polishing apparatus of claim 2, wherein:
the plurality of slits comprises at least 8 slits.

7. The carrier head for a chemical mechanical polishing apparatus of claim 1, wherein:
an inner surface of the outer ring comprises scalloping.

8. The carrier head for a chemical mechanical polishing apparatus of claim 7, wherein:
the scalloping comprises a first inner radius and a second inner radius; and
a difference between the first inner radius and the second inner radius is between about 0.05 mm and 2 mm.

9. The carrier head for a chemical mechanical polishing apparatus of claim 1, wherein:
a bottom surface of a contact member of the outer ring is elevated relative to the second surface of the inner ring.

10. The carrier head for a chemical mechanical polishing apparatus of claim 9, wherein:
a vertical distance between the bottom surface of the contact member of the outer ring and the second surface of the inner ring is between about 0.25 mm and 2 mm.

11. An inner retaining ring for a chemical mechanical polishing apparatus, comprising:
an annular body that is characterized by a first surface, a second surface opposite the first surface, an outer surface that extends between and couples the first surface and the second surface, and an inner surface that extends between and couples the first surface and the second surface, wherein:
the annular body defines a plurality of grooves through the second surface, with each of the plurality of grooves extending through a portion of a height of the inner ring; and
the annular body defines a plurality of slits that extend through the inner surface and the outer surface and that enable a lower end of the annular body to be radially displaceable.

12. The inner retaining ring for a chemical mechanical polishing apparatus of claim 11, wherein:
each slit has a width that is less than a width of each of the plurality of grooves.

13. The inner retaining ring for a chemical mechanical polishing apparatus of claim 11, wherein:
each of the plurality of slits extends through a top surface of a respective one of the plurality of grooves and extends through an additional portion of the height of the annular body.

14. The inner retaining ring for a chemical mechanical polishing apparatus of claim 13, wherein:
a number of the plurality of slits is equal to a number of the plurality of grooves.

15. The inner retaining ring for a chemical mechanical polishing apparatus of claim 13, wherein:
a height of each of the plurality of slits is greater than a height of each of the plurality of grooves.

16. The inner retaining ring for a chemical mechanical polishing apparatus of claim 13, wherein:
each of the plurality of slits is angled in a direction of rotation of the annular body with respect to a respective radial line extending from a center of the annular body.

17. The inner retaining ring for a chemical mechanical polishing apparatus of claim 13, wherein:
the plurality of slits comprises between about 8 slits and 90 slits.

18. A method of polishing a substrate, comprising:
flowing a polishing slurry from a slurry source to a polishing pad;
polishing a substrate atop the polishing pad; and
radially displacing at least a portion of a lower end of an inner ring that retains the substrate within a carrier head while polishing the substrate.

19. The method of polishing a substrate of claim 18, wherein:
radially displacing at least a portion of the lower end of the inner ring comprises displacing one or more islands of a plurality of islands in a radially outward direction; and
the plurality of islands are arranged about a circumference of the inner ring and are separated from one another by a plurality of slits defined within the inner ring.

20. The method of polishing a substrate of claim 18, wherein:
an outer ring having an inner surface is disposed against an outer surface of the inner ring;
the inner surface of the outer ring comprises scalloping;
the scalloping comprises an undulating pattern of regions having a first inner radius and regions having a larger second inner radius such that pockets are formed within each region having the second inner radius; and
radially displacing at least a portion of the lower end of the inner ring comprises deforming a portion of the inner ring into at least one of the pockets.
